(19) United States
(12) Patent Application Publication
(10) Pub. No.: US 2013/0134506 A1
(43) Pub. Date: May 30, 2013

(54) SEMICONDUCTOR DEVICE AND MANUFACTURING METHOD OF SAME

(71) Applicant: Atsushi YAGISHITA, Kanagawa-ken (JP)

(72) Inventor: Atsushi YAGISHITA, Kanagawa-ken (JP)

(73) Assignee: KABUSHIKI KAISHA TOSHIBA, Tokyo (JP)

(21) Appl. No.: 13/607,178

(22) Filed: Sep. 7, 2012

(30) Foreign Application Priority Data
Nov. 29, 2011 (JP) P2011-260808

(51) Int. Cl. H01L 29/78; H01L 21/336

(52) U.S. Cl. 257/330; 438/270; 257/E21.41; 257/E29.262

(57) ABSTRACT

A fin type semiconductor layer is formed on a substrate with a source and a drain. A dummy gate is formed crossing the fin type semiconductor layer. After depositing an insulating film on the dummy gate, the upper surface of the dummy gate is exposed. The dummy gate is then removed to form a gate trench. On the surface of the fin type semiconductor layer in the gate trench, a gate insulating film is formed. Material for a gate electrode is filled in the gate trench and etched to form the gate electrode. The height of the upper surface of the gate electrode is equal to or lower than the height of the upper surface of the fin type semiconductor layer at the source and the drain, and is equal to or higher than the height of the upper surface of the fin type semiconductor layer in the gate trench.

### CROSS-REFERENCE TO RELATED APPLICATION

This application is based upon and claims the benefit of priority from Japanese Patent Application No. 2011-260808, filed Nov. 29, 2011; the entire contents of which are incorporated herein by reference.

### FIELD

Embodiments described herein relate to a semiconductor device and its manufacturing method.

### BACKGROUND

In recent years, for the DRAM (dynamic random access memory), MRAM (magnetoresistive random access memory), and other memories, there has been a narrowing of the gate spacing between the adjacent cell transistors. Within this narrowed spacing between the gates, it is necessary to form the source contact and drain contact. However, as the spacing between the gate electrode and the contact plug is narrowed, the electrical parasitic capacitance between the gate electrode and the contact plug increases. In addition, short circuit may occur between the gate electrode and the contact plug when they are located closely together.

Also, the memory are made finer, i.e., more closely spaced or packed, the width of the gate electrode itself also becomes narrower. However, in order for the gate electrode to meet the RC specifications of various types of memories (3 nanoseconds or shorter), the resistance value of the gate electrode has to be decreased. In order to decrease the resistance value through the narrow gate electrode, the height of the gate electrode has to be raised, and its aspect ratio has to be increased. As gate electrodes are now made narrower, in the manufacturing operation it is difficult to form the gate electrodes evenly with a high aspect ratio.

### DESCRIPTION OF THE DRAWINGS

FIG. 1A is a perspective view illustrating a step in the manufacturing method of an embedded gate transistor for an MRAM device according to an embodiment.

FIG. 1B is a cross-section view of FIG. 1 at section B-B.

FIG. 2 is a perspective view of a manufacturing precursor of the embedded gate transistor for an MRAM device of FIG. 1, having an additional material layer deposited thereon.

FIG. 3 is a perspective view of a manufacturing precursor of the embedded gate transistor for an MRAM device of FIG. 2, following an ion implantation step thereon.

FIG. 4A is a perspective view of a manufacturing precursor of the embedded gate transistor for an MRAM device of FIG. 3, following a gate electrode formation and an etch step thereon.

FIG. 4B is a sectional view of FIG. 4A taken at section B-B.

FIG. 5A is a perspective view of a manufacturing precursor of the embedded gate transistor for an MRAM device of FIG. 4, following a spacer formation and the additional etch step thereon.

FIG. 5B is a sectional view of FIG. 5A at section B-B.

FIG. 6A is a perspective view of a manufacturing precursor of the embedded gate transistor for an MRAM device of FIG. 5 following an epitaxial deposition step thereon.

FIG. 6B is a perspective view of FIG. 6A at section B-B.

FIG. 7A is a perspective view of a manufacturing precursor of the embedded gate transistor for an MRAM device of FIG. 6 following dielectric deposition step thereon.

FIG. 7B is a perspective view of FIG. 6A at section B-B.

FIG. 8A is a perspective view of a manufacturing precursor of the embedded gate transistor for an MRAM device of FIG. 7 following an etch step thereon.

FIG. 8B is a perspective view of FIG. 8A at section B-B.

FIG. 9A is a perspective view of a manufacturing precursor of the embedded gate transistor for an MRAM device of FIG. 8 following an barrier layer formation and metal gate deposition step thereon.

FIG. 9B is a perspective view of FIG. 9A at section B-B.

FIG. 10A is a perspective view of a manufacturing precursor of the embedded gate transistor for an MRAM device of FIG. 9 following an etching and dielectric hard mask deposition step thereon.

FIG. 10B is a perspective view of FIG. 9A at section B-B.

FIG. 11A is a perspective view of the embedded gate transistor for an MRAM device of FIG. 10 following an etch step and the silicidation step thereon.

FIG. 11B is a perspective view of FIG. 11A at section B-B.

FIG. 12A is a perspective view of the embedded gate transistor for an MRAM device following contact formation to the source and drain thereof.

FIG. 12B is a perspective view of FIG. 12A at section B-B.

FIG. 13 is a plane view illustrating the MRAM of the embodiment.

FIG. 14 is a diagram illustrating the configuration of a single memory cell MC.

FIG. 15 is a sectional view taken at section 15-15 in FIG. 13.

FIG. 16 is a sectional view taken at section 16-16 in FIG. 13.

FIG. 17 is a sectional view taken at section 17-17 in FIG. 13 and FIG. 15.

FIG. 18 is a sectional view taken at section 18-18 in FIG. 13 and FIG. 15.

FIG. 19 is a schematic a perspective view of the cell transistor CT illustrating the correlation between a gate electrode, a fin type semiconductor layer and an epitaxial layer.

### DETAILED DESCRIPTION

In general, embodiments of the present disclosure will be explained with reference to figures. However, the present disclosure is not limited to the depictions found in the figures.

According to a first embodiment, there is provided a semiconductor device and its manufacturing method, whereby the height of an uppermost surface of a gate electrode is lowered, so that manufacturing becomes easier, the parasitic capacitance between the gate electrode and the contact plug can be suppressed, and so that it is possible to avoid the occurrence of short circuiting between the gate electrode and the contact plug.

According to the manufacturing method of the semiconductor device in this embodiment, a fin type semiconductor layer is formed on a substrate. A dummy gate electrode is formed transverse to and through the fin type semiconductor layer. On the fin type semiconductor layer, the source and drain are formed. After depositing an interlayer insulating film on the dummy gate electrode, the upper surface of the dummy gate electrode is exposed. The dummy gate electrode is then removed to form a gate trench. The upper portion of the fin type semiconductor layer exposed in the gate trench is etched back. On the exposed surfaces of the fin type semiconductor layer in the gate trench, a gate insulating film is formed. The gate trench is filled with the material of the gate electrode, which is then etched back to form the gate electrode. The uppermost surface of the gate electrode is below upper surfaces of the fin type semiconductor layer at the source and the drain in the initial stage, and the gate electrode remains disposed in the gate trench, over a surface of the semiconductor material from which the fins are formed.

The semiconductor devices according to the following embodiments can be adopted in the cell transistors of, DRAM, MRAM, and other memories. Also, the semiconductor devices, according to the embodiments, also can be adopted in the transistors of the Logic-LSI including SRAM and other memories.

### Embodiment 1

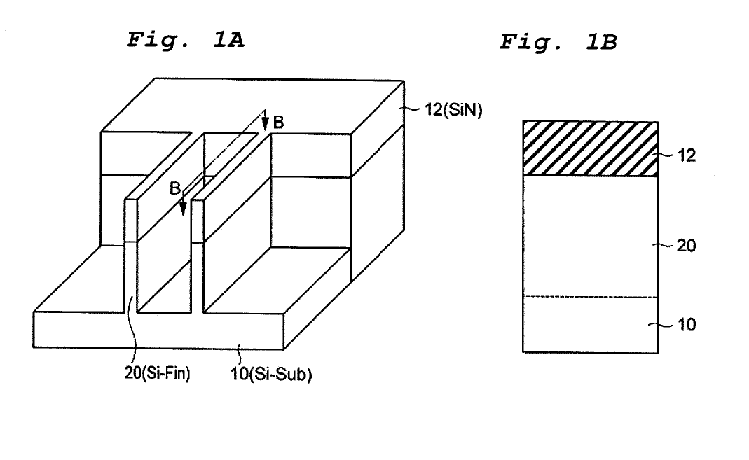

FIG. 1A through FIG. 12B are perspective and cross-sectional views illustrating the manufacturing method of the fin type semiconductor device of Embodiment 1. Where there are two figures on one page (an A and a B figure), the second (B) figure is a cross-sectional view taken across line B-B of the first (A) figure.

First of all, a bulk silicon substrate 10 is prepared as a semiconductor substrate. On the silicon substrate 10, a hard mask 12 is deposited. The hard mask is then patterned, using a photolithographically processed resist layer and reactive ion etch (RIE), to form a mask having the outline of the fins to be formed in the underlying silicon layer 20. For example, the hard mask 12 may be made of silicon nitride film or other insulating film.

Then, with the hard mask 12 used as a mask, the silicon substrate 10 is etched using the RIE method. As a result, as shown in FIG. 1A and FIG. 1B, trenches for device isolating STI (shallow trench isolation) are formed. Also, as a result of the etching, fins 20 are configured or etched into the underlying silicon substrate 10. The fin type semiconductor layer 20 comprises multiple protrusions or fins which extend as fins oriented generally perpendicular to the plane of the 10. The width of each of these fin type semiconductor layers 20 is approximately 15 nm. The fin type semiconductor is configured, by the addition of dopants thereto, as an active area in a FINFET Transistor to be formed on the substrate 10.

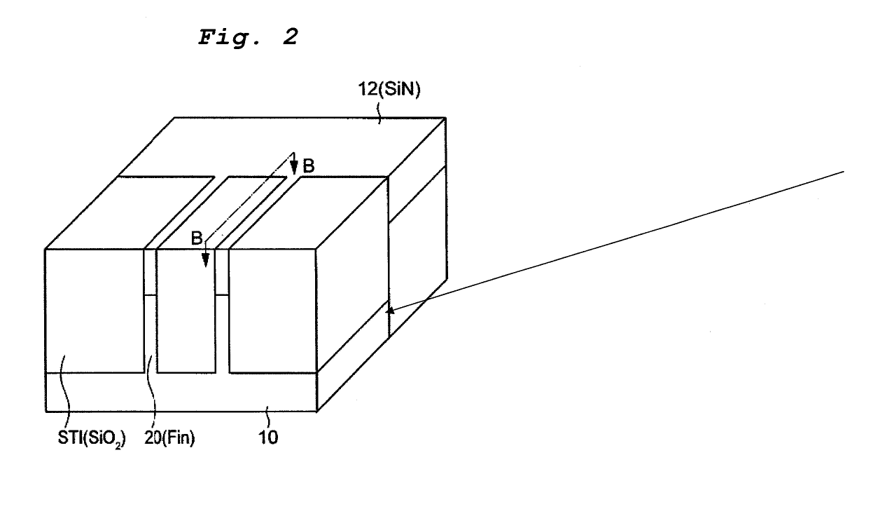

As shown in FIG. 2an insulating film is deposited using polysilazane or another chemical vapor deposition source gas to fill the just etched regions of the substrate, and is thereafter polished, by means of CMP (chemical mechanical polishing), to yield a planar SiO₂ insulating film adjacent to the fins 20 to provide shallow trench isolation.

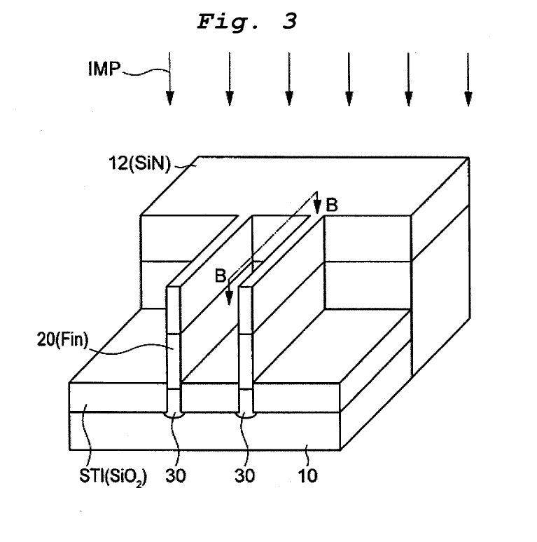

Then, to yield the profile as shown in FIG. 3, the insulating film is etched back by means of wet etching. A portion of the insulating film (STI) is left on the bottom portion of the trench following etching. Furthermore, in this process, two side surfaces of the fin type semiconductor layer 20 are exposed where insulating film was etched back. As a result, the height of the fin type semiconductor layer 20 is set as the span of the fin extending above the remaining insulating (STI) film.

Then, as shown in FIG. 3, impurity dopant or impurity is implanted to form a diffusion layer 30 that provides a punch-through stopper in the lower portion of the fin type semiconductor layer 20. For example, the impurity may be boron or another P type impurity. As the dopant is ion implanted from above the surface of the silicon substrate 10, the dopant travels through the insulating layer and is implanted into the base of the fins 20 to form the diffusion layer in the lower portion of the fins 20.

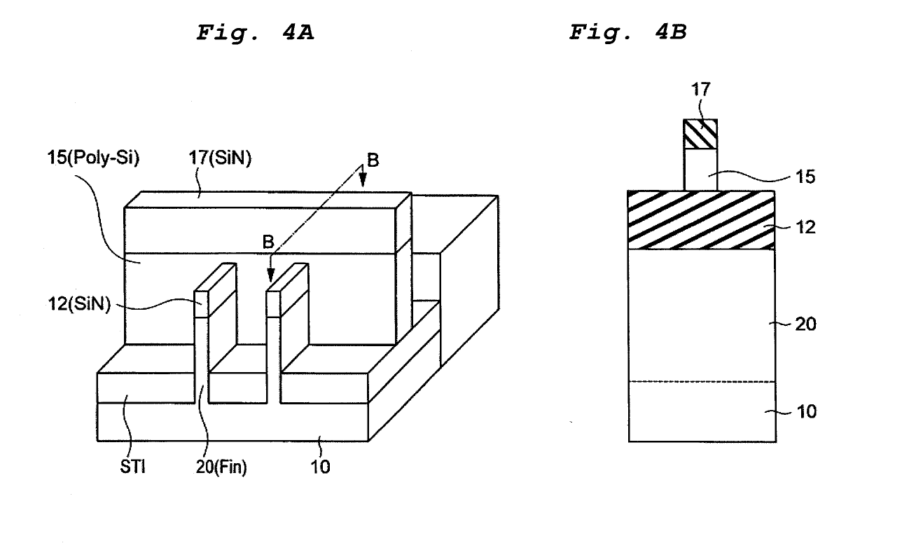

A series of subsequent steps will now be described by referring to FIG. 4A and FIG. 4B. In the next step of the fabrication process, a dummy gate electrode 15 is formed on the fin type semiconductor layer 20 and the device isolating STI insulating layer by the steps of depositing a polysilicon layer and a silicon nitride hardmask layer, patterning the hardmask layer, and using the hardmask layer to etch a dummy pattern in the polysilicon having the dimension of a later to be formed gate electrode.

Hard mask layer 17 is patterned to form the outline of a dummy gate 20 in the underlying polysilicon layer, and then the hard mask layer 17 is used as an etch mask to etch the dummy gate electrode 15 and the polysilicon using the RIE method. As a result, the structure shown in FIG. 4A and FIG. 4B is obtained. The dummy gate electrode 15 extends lengthwise across the trenches and the fins 20. In this case, the remaining, post-etch, height of the hard mask layer 17 and dummy gate 15 is greater than the height of the fins 20 and the hard mask layer 12 remaining thereon.

Then, a material used to form the side walls 19 of the gate is deposited on the fins 20 and the dummy gate electrode 15. In this case, the material for forming the side wall 19 is deposited around and over the fin type semiconductor layer 20 and the dummy gate electrode 15. For example, the material of the side wall film 19 may be a silicon nitride film or other insulating film, depositing using a silicon precursor and a nitrogen source gas, using cvd processes. The material may be deposited only over the flanks of the dummy gate 15, hardmask 17 and adjacent portions of the fins 20 by first forming a masking layer having a gap adjacent to the sidewalls of the dummy gate 15 into which the side wall film may be deposited, or, a blanket silicon nitride film may be deposited over the exposed surfaces of the dummy gate 15, hard mask 17, fins 20 and isolation layer, and patterned to remove the portions thereof extending over the fins 20 and isolation layer (STI), while protecting the that formed on the sidewalls of the dummy gate 15 and hard mask.

Thereafter, the side wall material is anisotropically etched, so that the side walls 19 is left on the side surfaces of the dummy gate electrode 15 and hard mask layer 17. The material of the side wall film 19 is removed from the side and top surfaces of the fin type semiconductor layer 20, while it is again left on the side surface of the dummy gate electrode 15.

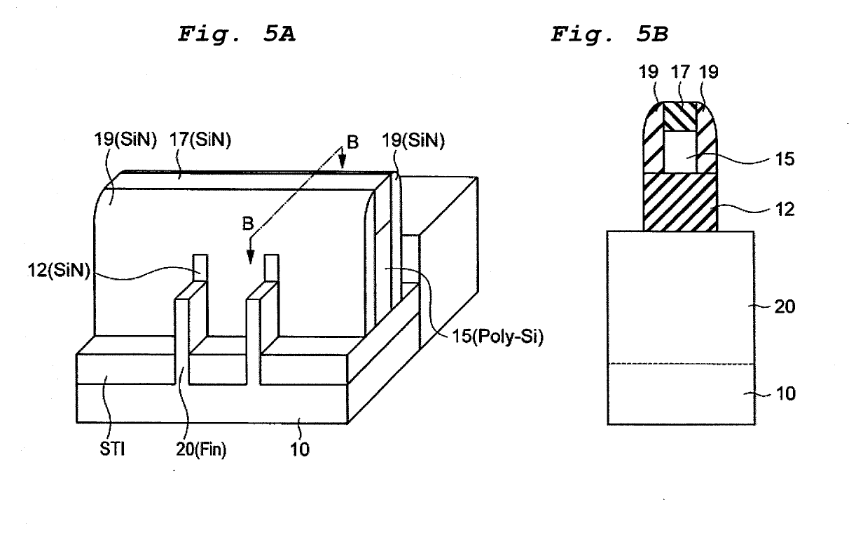

As a result, as shown in FIG. 5A and FIG. 5B, while the side wall film 19 remains on the side surface of the dummy gate electrode 15, it is possible to remove the material of the side wall film 19 from the sides and upper surface of the fins 20.

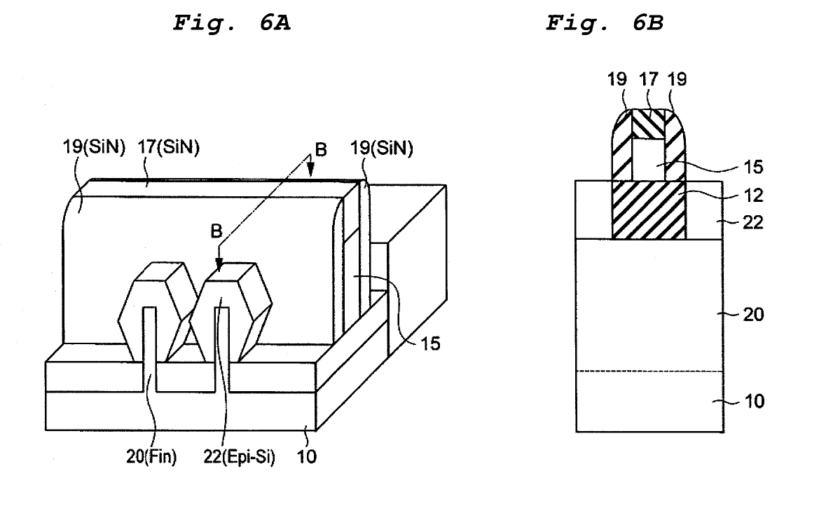

Subsequent steps will be described now with reference to FIG. 6A and FIG. 6B. In order to form an extrusion layer, ion implanting is performed. The concentration of ions is approximately 1E19 cm⁻³.

Then, silicon is epitaxially grown to cover exposed side surfaces of the fin type semiconductor layer 20 and a portion of the side surfaces of the side wall film 19. As a result, as shown in FIG. 6A and FIG. 6B, an epitaxial silicon layer 22 is formed on both the source and drain regions, which each are located at one of opposite sides of dummy gate electrode 15. In this case, silicon is formed not only on the side surfaces of the fins 20, but also on its upper surfaces. Consequently, the upper surfaces of the epitaxial layer 22 are higher than the upper surface of the fin 20.

Next, an N type impurity is ion implanted into the epitaxial layer 22. For example, the N type impurity may be arsenic or phosphorus, and its concentration is approximately 1E20 cm⁻³. Then, the epitaxial layer 22 is annealed at about 1000° C. These processes result in the source and drain being formed in the fins 20 and the epitaxial layer 22, the source and the drain corresponding to aligned fins extending on either side of the dummy gate 15.

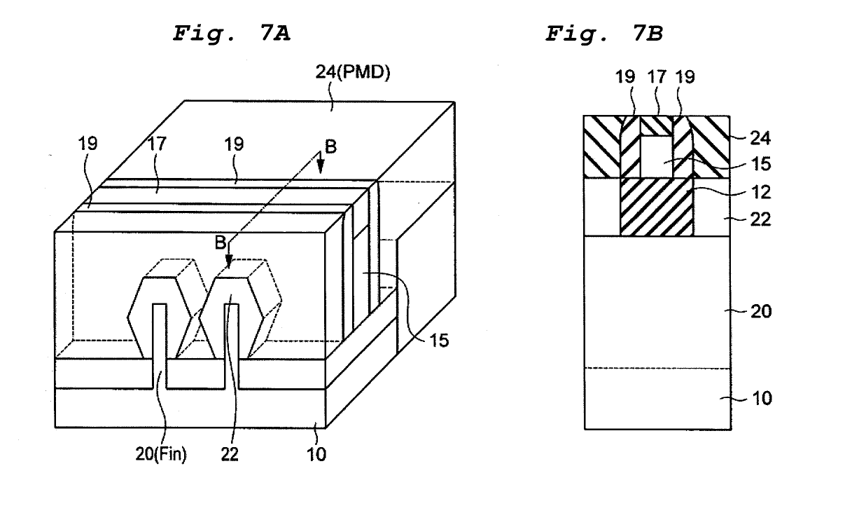

Then, an interlayer, or pre-metallization dielectric layer 24 (PMD) is deposited on the silicon substrate 10 so that the epitaxial layer 22, side wall film 19, hard mask 17, etc. are covered thereby. The deposited material 24 is the same material as was used to form the interlayer insulating film. The material of the interlayer insulating film 24 may be a silicon oxide film formed using TEOS, or another insulating film. Then, by means of CMP, the interlayer insulating film 24 is polished until the upper surface of the hard mask 17 is exposed. As a result, the structure shown in FIG. 7A and FIG. 7B is obtained.

Then, by means of wet etching, the exposed hard mask 17 above the dummy gate electrode 15 is selectively removed, and the dummy gate electrode 15 beneath the hard mask 17 is also selectively removed. As a result, gate trench TG is formed between the side wall film portions 19.

At the bottom of the gate trench TG, the portion of the hardmask hard mask 12 originally used to pattern the fins 20 is exposed by the wet etching, but the wet etchant is not sufficiently reactive with this material to remove it. Therefore, an RIE method is adopted to remove the portion of the hard mask 12 below the gate trench TG, and recess a portion of the dielectric spacer 19 adjacent to the top of the feature. As a result, the portion of the top surface of the fin 20 previously covered by the dummy gate electrode 15 and hard mask 12 is exposed at the bottom of the gate trench TG. Then, by the RIE method, the upper portion of the fin 20 is etched away to create for the receipt (trench in fin channel) of the gate electrode.

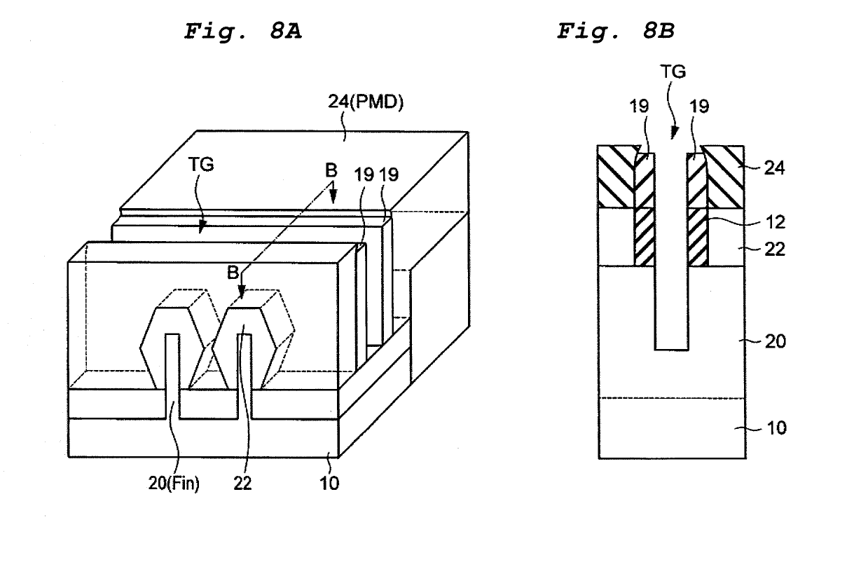

As a result, as shown in FIG. 8A and FIG. 8B, a trench is etched in the underlying silicon forming the fin extending through the gate region, whose bottom is higher than the surface of the previously deposited oxide or insulating film forming the shallow trench isolation, to a depth of about 20 nm-40 nm.

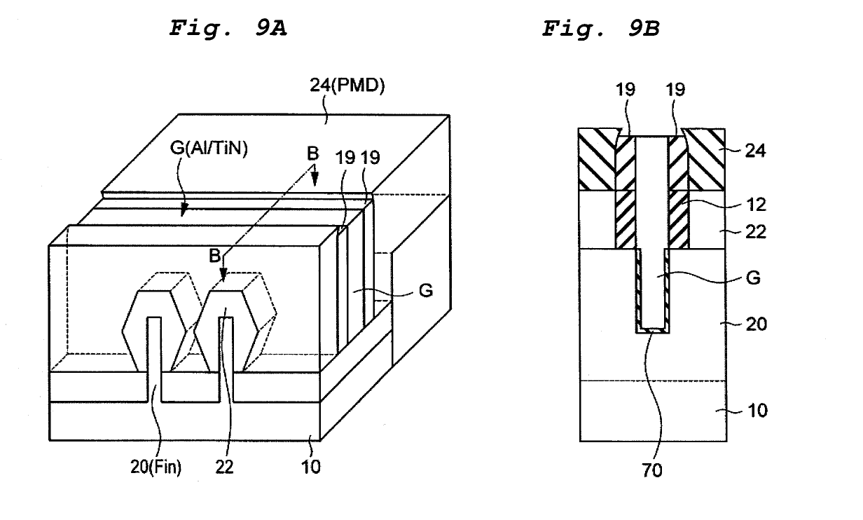

Then, as shown in FIG. 9B, a gate insulating film 70 is formed on the exposed surfaces of the fin type semiconductor layer 20 within the gate trench TG. For example, the gate insulating film 70 may be made of a silicon oxide film or an insulating film with a dielectric constant higher than that of silicon oxide film, such as by in situ oxidation of the exposed portions of silicon portion of the trench. Then, the material used to form the gate electrode G is deposited in the gate trench TG and is also formed over upper surfaces of side wall film 19 and interlayer insulating film 24. Then a CMP step is carried out to polish the material of the gate electrode G until the upper surfaces of the interlayer insulating film 24 and upper surfaces of the side wall film 19 are exposed. As a result, the structure of the gate electrode G shown in FIG. 9A and FIG. 9B is obtained.

The material of the gate electrode G may be an Al plug formed over a TiN trench lining film, or another low-resistivity metal. Here, when the gate electrode G is formed, the high temperature annealing for forming the source S and drain D has already been performed. Consequently, the gate electrode G may be made of aluminum or other low melting point metal.

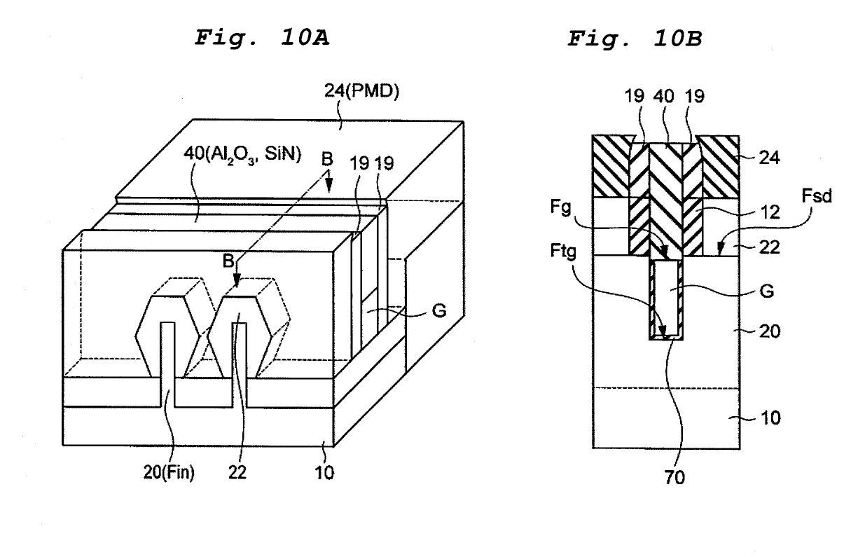

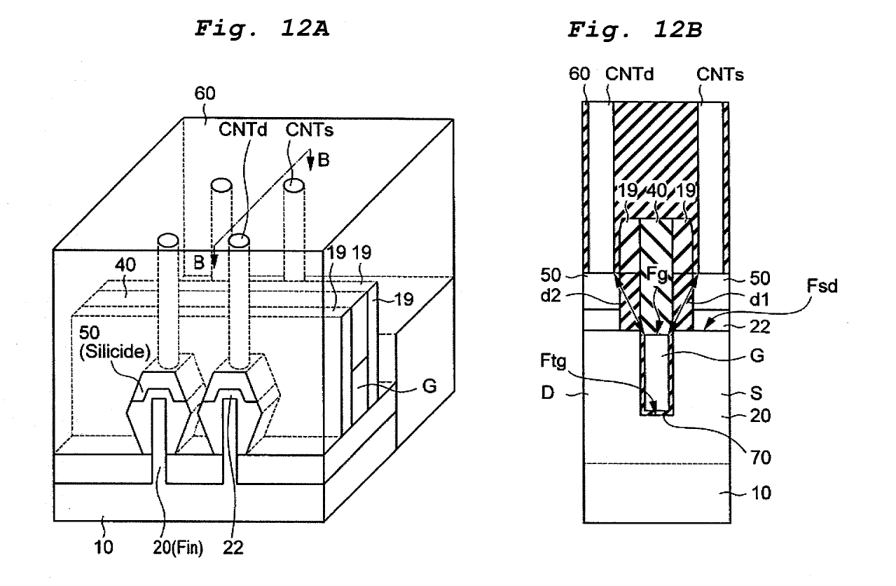

Next, the gate electrode GC is etched back. Also, at this point, in order to widen the spacing between the contact plugs CNTs, CNTd (see FIG. 12) and the gate electrode G, the upper surface Fg of the gate electrode G is lower than the upper surface Fsd of the adjacent fins 20 at the parts of the semiconductor layer 20 which are associated with the source and drain and located to the side of the gate trench. The thickness of the gate electrode G left overlying the remaining fin 20 material and structure in the gate trench TG is, for example, about 20 nm. Thus, as seen in FIG. 10B, the gate G is embedded into the silicon of the fin 20, and epitaxial silicon regions 22 are present on either side of, and above, the gate G, and portions of the fins 20 extend to either side, and under, the gate G.

Next, a material used to form hard mask 40 is deposited on the gate electrode G and on upper surfaces of side wall film 19 and interlayer insulating film 24. The material of the hard mask 40 may be Al₂O₃, SiN, or another insulating film. For example, when SiN is used, CMP is carried out so that the material of the hard mask 40 is polished until the interlayer insulating film 24 and side wall film 19 is exposed. As a result, as shown in FIG. 10A and FIG. 10B, the gate electrode G embedded in the gate trench and the hard mask 40 covering the upper surface of the gate electrode GC are formed. As a result, the structure of the embedded gate type FinFET is obtained. Also, the hard mask 40 may be formed by depositing Al₂O₃, followed by etching back the deposited Al₂O₃. However, it may also be formed by oxidation of the gate electrode G.

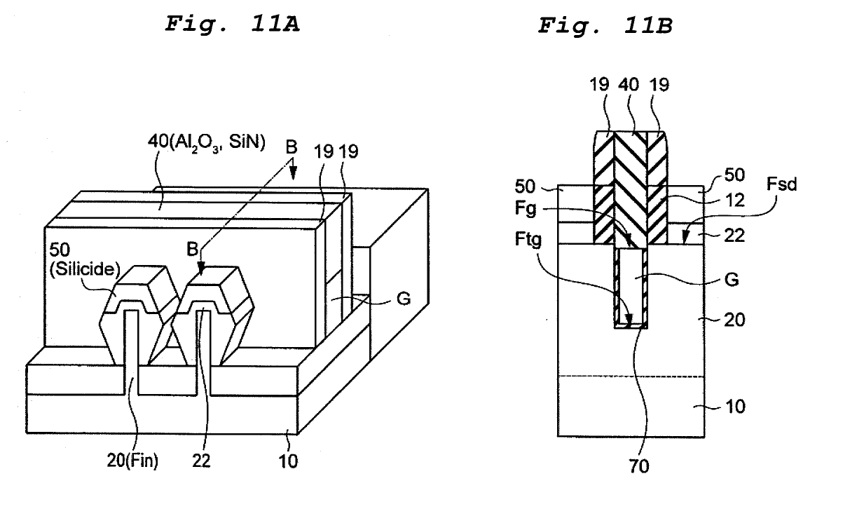

Then, the interlayer insulating film 24 is etched back to expose top surfaces of the epitaxial layer 22. The interlayer insulating film 24 may be entirely removed, as depicted in FIG. 11A, or it may be removed so that a desired portion of the upper surfaces of the epitaxial layer 22 is exposed.

Then, a metal film is deposited on the epitaxial layer 22, followed by heat treatment. As shown in FIG. 11A and FIG. 11B, these processes result in a silicide layer 50 disposed on the epitaxial layer 22 (source and drain). The metal film may be formed from nickel or other metal material. Asa result, the silicide layer 50 becomes, for example, nickel silicide.

Then, an interlayer insulating film 60 is deposited on the silicide layer 50, hard mask 40, and side wall film 19. The interlayer insulating film 60 may be an insulating film of PSZ (polysilazane) or the like. After flattening of the interlayer insulating film 60 by CMP, contact holes reaching the silicide layer 50 are formed. Next, a metal material (such as a tungsten plug deposited over a previously deposited TiN liner) is formed in the contact holes. In this way, as shown in FIG. 12A and FIG. 12B, contact plugs CNTs, CNTd are formed. Here, contact plug CNTs is connected to the silicide layer 50 on the source side, and contact plug CNTd is connected to the silicide layer 50 on the drain side.

Then, MTJ elements etc., are formed on the contact plug CNTd or contact plug CNTs, and the MRAM of this embodiment can be completed.

According to the present embodiment, by using the dummy gate electrode 15, after the high temperature annealing treatment when the source S and drain D are formed, the metal gate electrode GC is formed. As a result, the gate electrode GC is formed by a metal material too weak to heat (for example, aluminum or the like).

In addition, according to the present embodiment, the silicide layer 50 is formed after formation of the gate insulating film 70 and the gate electrode GC. Consequently, the silicide layer 50 does not receive the heat treatment when the gate insulating film 70 is formed. As a result, it is possible to form the silicide layer 50 with the desired composition and shape.

As shown in FIG. 12B, the upper surface Fg of the gate electrode GC is lower than the upper surface Fsd of the portions of the fin type semiconductor layer 20 associated with either the source S or drain D. Consequently, there is increased distance d1, d2 between the gate electrode GC and the contact plugs CNTs, CNTd. As a result, it is possible to decrease the electrical parasitic capacitance occurring between the gate electrode GC and the contact plugs CNTs, CNTd. Furthermore, it is possible to suppress a short circuit between the gate electrode GC and the contact plugs CNTs, CNTd.

In order to further lower the upper surface Fg of the gate electrode GC, after removal of the dummy gate electrode 15, the recess formed in the fin type semiconductor layer 20 may be made deeper. As a result, although the upper surface Fg of the gate electrode GC is lowered, the gate electrode GC can still be formed to have a continuous volume over the same area, and a continuous connection can be realized.

The hard mask 40 covers the upper surface of the gate electrode G. Consequently, even if misalignment occurs when forming the contact plugs PLGs, PLGd, because the gate electrode GC is protected by the hard mask 40, no short circuit involving the contact plugs PLGs, PLGd takes place for.

In addition, according to the present embodiment, the gate electrode GC is made of aluminum, a material with lower resistivity than other metals such as tungsten, TiN, etc., which are conventionally adopted as the material for gate electrodes. Consequently, it is possible to lower the height of the gate electrode GC by forming a deeper gate trench TG.

Because the FinFET has embedded type gate electrodes G on the two sides of the channel portion, it has a high current driving ability. The FinFET of the present embodiment can be adopted in the cell transistors of MRAM, so that the data write operation of MRAM can be carried out easily.

The impurity implanting operation when the source S and drain D are formed is carried out after formation of the epitaxial layer 22. In addition, by executing activation annealing of the source S and drain D after formation of the epitaxial layer 22, it is possible to feed the impurity evenly to the entirety of the fin type semiconductor layer 20 and epitaxial layer 22 of the source/drain region. As a result, it is possible to increase the driving current of the cell transistors.

When the SMT (stress memorization technique), SiC source/drain and other mobility booster schemes are adopted in the manufacturing method of this embodiment, after removal of the dummy gate electrode 15, the gate electrode GC is embedded in the gate trench TG, so that the stress applied on the fin type semiconductor layer 20 is increased, and the mobility of the carriers in the cell transistors CT is improved.

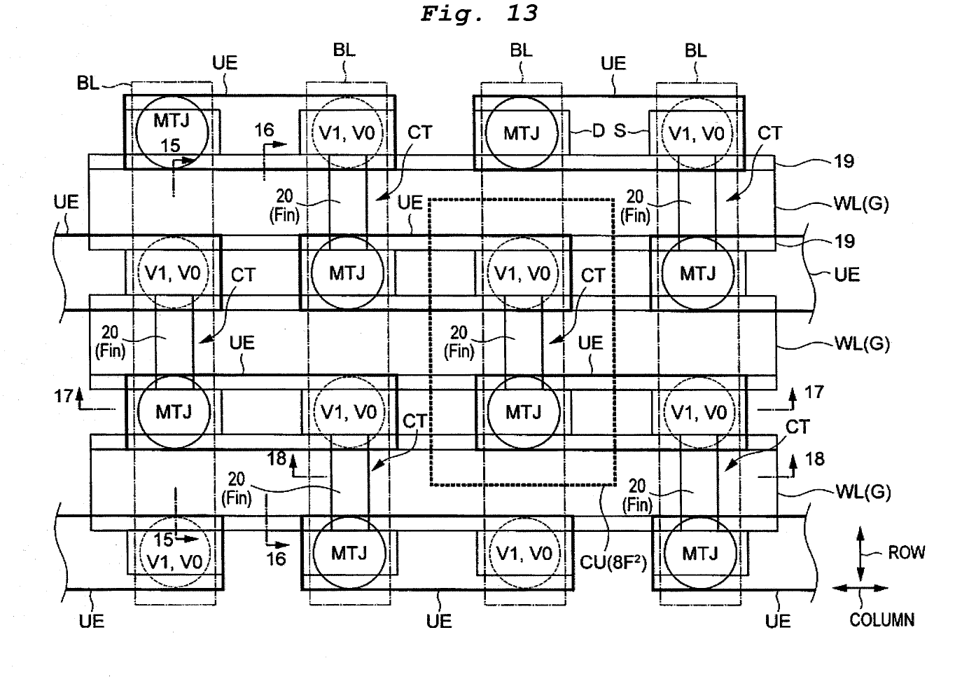

FIG. 13 is a plane view of the MRAM of the present embodiment. The MRAM of the present embodiment has the cell transistors CT manufactured using the manufacturing method and magnetic tunnel junction element (MTJ element) formed above the interlayer insulating film 60 and the contact plug CNTd (or contact plug CNTs).

In the planar layout shown in FIG. 13, the pattern of the cell unit CU containing one cell transistor CT and one magnetic tunnel junction element is repeated in the row direction. The patterns of the two cell units CU adjacent to each other in the column direction are shifted from each other by half the pitch in the row direction. That is, the cell units CU in the adjacent rows are shifted from each other by half the pitch in the row direction. In company with this configuration, the MTJ elements and the via contacts V0, V1 are arranged alternately in the column direction and row direction. Here the size of the cell unit CU is 8F², where F (feature size) represents the minimum processing dimension in the semiconductor process.

The via contact V0 is electrically connected to the source S of the cell transistor CT and the upper electrode UE. The via contact V1 is electrically connected between the upper electrode UE and the bit line BL. In order to electrically connect the upper portion of the MTJ element to the bit line BL, the upper electrode UE is connected between the upper portion of the MTJ element and the via contact V1. In addition, the upper electrode UE is also connected between the MTJ element and the via contact V0.

The fin type semiconductor layer portions 20 correspond to the cell units CU, and they are formed in a zigzag layout. A cell transistor CT is formed corresponding to each fin type semiconductor layer portion 20.

Several gate electrodes GC extend in the column direction, and they work as multiple word lines WL. Also, several gate electrodes GC are connected to multiple word lines WL, respectively. The multiple bit lines BL extend in the row direction orthogonal to the word lines WL. The MTJ elements and cell transistors CT of the various cell units CU are connected in tandem beneath the bit lines BL. In the data write or data read state, the cell transistor CT of the selected cell unit CU becomes the conductive state, and the MTJ element and the cell transistor CT of the selected cell unit CU are connected between two bit lines BL.

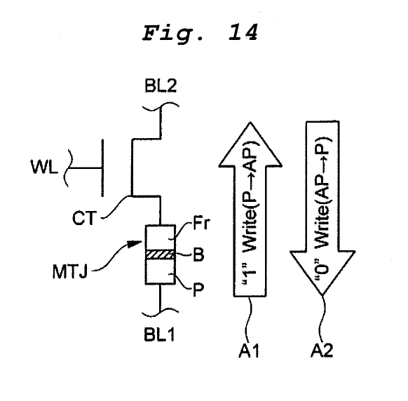

FIG. 14 is a diagram illustrating the configuration of a single memory cell MC. Each memory cell MC contains an MTJ element (magnetic tunnel junction element) and a cell transistor CT. The MTJ element and the cell transistor CT are connected in tandem between bit line BL1 and bit line BL2. In the memory cell MC, the cell transistor CT is arranged on the side neighboring the bit line BL2, and the MTJ element is arranged on the side neighboring the bit line BL1. The gate of the cell transistor CT is connected to the word line WL. Here, the bit lines BL1, BL2 may be any two bit lines BL adjacent each other.

The MTJ element exploits the TMR (tunneling magnetoresistive) effect, and it has a laminated structure having two ferromagnetic layers and a nonmagnetic layer (insulating film) sandwiched between them. By means of the spin polarization tunnel effect, the magnetic resistance is changed so that the digital data are stored. For the MTJ element, corresponding to the combination of magnetization of the two ferromagnetic layers, a low resistance state and a high resistance state can be realized. For example, if the low resistance state is defined to be data 0, and the high resistance state is defined to be data 1, each MTJ element can record 1-bit of data. Of course, one may also define the low resistance state as data 1 and the high resistance state as data 0. For example, as shown in FIG. 14, the MTJ element is formed by sequentially laminating an anchoring layer P, a tunnel barrier layer B, and a recording layer Fr. The anchoring layer P and recording layer Fr are made of ferromagnetic materials. The tunnel barrier layer B is made of an insulating film. The anchoring layer P is for anchoring the orientation of the magnetization. The recording layer Fr allows change of the orientation of magnetization so that data can be stored corresponding to the orientation of the magnetization.

In the write operation, when a current over the inversion threshold current flows in the direction indicated by the arrow Al, the orientation of the magnetization in the recording layer Fr becomes the anti-parallel state with respect to the orientation of the magnetization of the anchoring layer P, and the high resistance state (data 1) is set up. On the other hand, in the write operation, when a current over the inversion threshold current flows in the direction indicated by arrow A2, the magnetization orientation of the anchoring layer P and that of the recording layer Fr become parallel with each other, and the low resistance state (data 0) is set up. In this way, the MTJ element allows writing of different data corresponding to different current directions.

In the data read operation of the MRAM, the sense amplifier S/A detects the difference in the resistance value of the memory cell MC due to feeding current (cell current) to the memory cell MC. In this case, the cell current is higher than the inversion threshold current for the write operation.

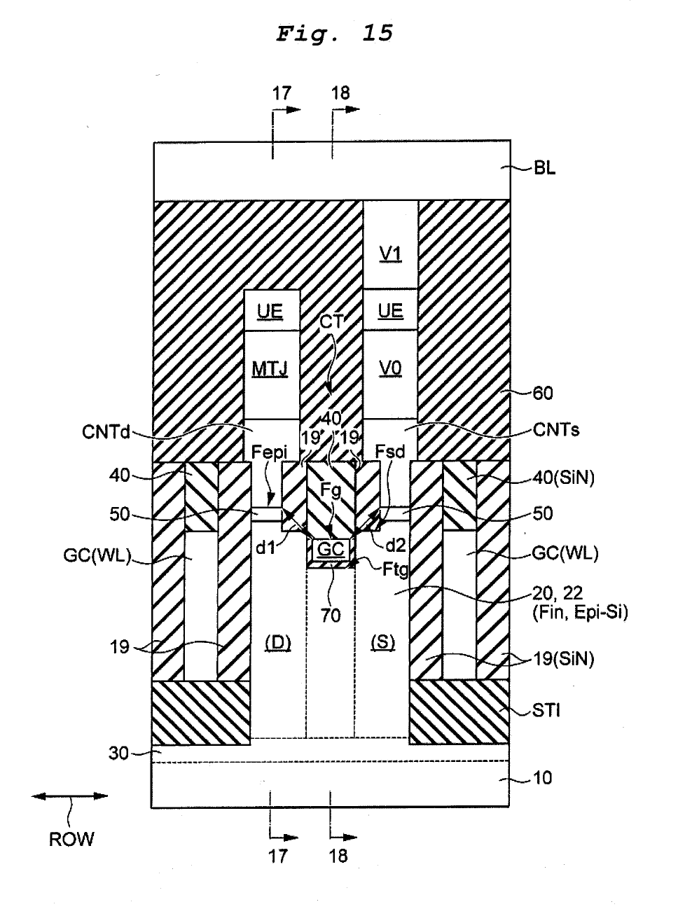

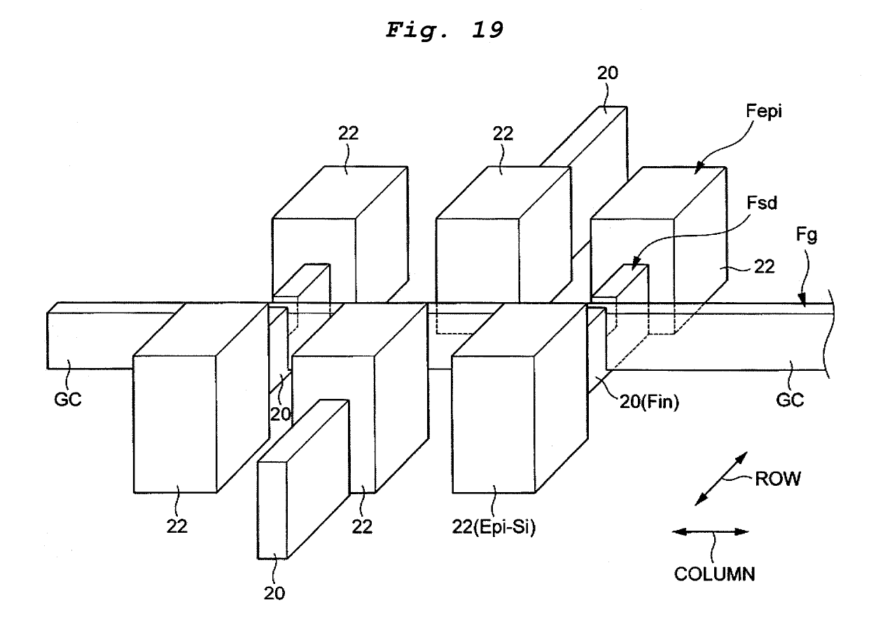

FIG. 15 through FIG. 18 are cross-sectional views taken across 15-15 in FIG. 13, a cross-sectional view taken across 16-16 in FIG. 13, a cross-sectional view taken across 17-17 in FIG. 13 and FIG. 15, and a cross-sectional view taken across 18-18 in FIG. 13 and FIG. 15, respectively. FIG. 19 is perspective view of the cell transistor CT, and illustrates schematically the position of the gate electrode GC, the fins 20 and the epitaxial layer 22.

As shown in FIG. 15, the MRAM according to the present embodiment has a silicon substrate 10, fins 20 formed on and extending from the silicon substrate 10, source S and drain D formed in the fins 20, gate electrodes GC disposed perpendicular to the lengthwise direction of the fin type semiconductor layer 20, and upper insulating films 40 arranged on the upper surface of the gate electrode GC.

The gate electrode GC, source S and drain D form each cell transistor CT. The channel portion of the cell transistor CT is arranged between the source S and the drain D. The diffusion layer 30 is arranged as the punch-through stopper beneath the channel portion. The gate electrode GC is insulated from the source S, drain D and channel portion by the gate insulating film 70. The silicide layer 50 is arranged on the epitaxial layer 22 and the fin type semiconductor layer 20.

The hard mask 40 and side wall film 19 are formed as the upper insulating film on the gate electrode GC. Here, the hard mask 40 and side wall film 19 may be put together and referred to as upper insulating films 19, 40. The upper insulating films 19, 40 are arranged and included between the gate electrode GC and the contact plugs CNTs, CNTd. As shown in FIG. 15, where width is assumed to be measured in the row direction, the width of the upper insulating films 19, 40 is wider than the width of the gate electrode GC. As a result, spacings d1, d2 between the gate electrode GC and the contact plugs CNTs, CNTd are widened, so that it is possible to decrease the parasitic capacitance between the gate electrode GC and the contact plugs CNTs, CNTd. In addition, the upper insulating films 19, 40 can suppress a short circuit between the gate electrode GC and the contact plugs CNTs, CNTd. Also, by arranging the upper insulating films 19, 40, the contact holes of the contact plugs CNTs, CNTd can be formed in a self aligned way.

The contact plugs CNTs, CNTd are connected to the source S and drain D. The MTJ element is arranged on the contact plug CNTd. The contact plug CNTd electrically connects the lower portion of the MTJ element to the drain D of the cell transistor CT. The upper portion of the MTJ element is connected to the upper electrode UE. As a result, the MTJ element is electrically connected between the upper electrode UE and the drain D of the cell transistor CT.

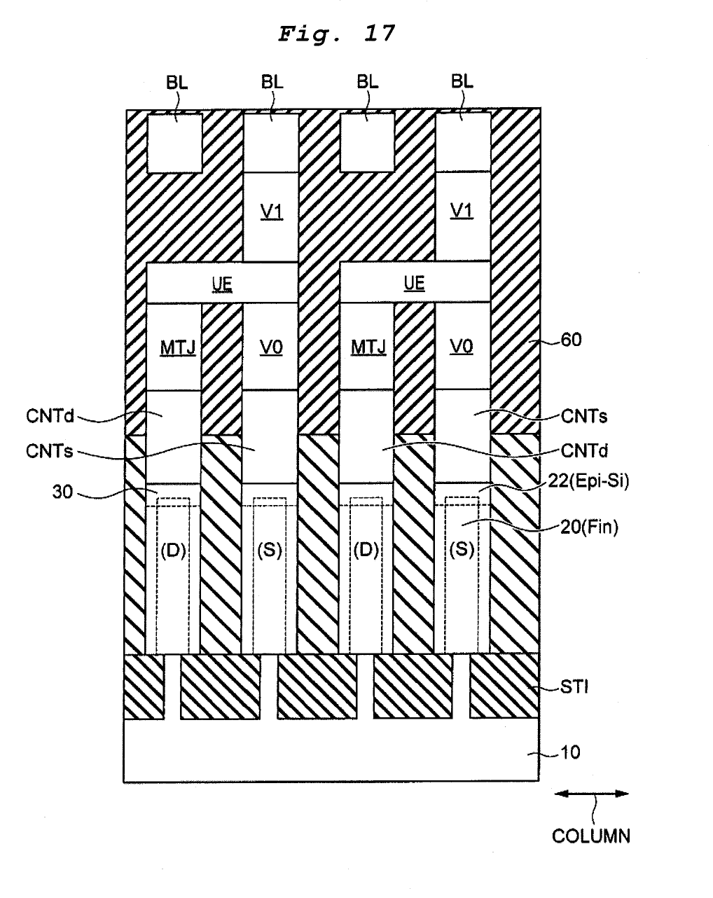

On the other hand, contact plug CNTs is connected to the upper electrode UE through the via contact V0. The upper electrode UE is electrically connected to the bit line BL through the via contact V1. In addition, the upper electrode UE extends lengthwise in the column direction as shown in FIG. 17, and it electrically connects the upper portion of the MTJ element and the portion between the via contact V0 and via contact V1. As a result, the MTJ element and the cell transistor CT are connected in tandem between two adjacent bit lines BL.

As shown in FIG. 15 and FIG. 19, the height of the upper surface Fg of the gate electrode GC is lower than the height of the upper surface Fsd of the portion of fin type semiconductor layer 20 in the source S and drain D, and higher than the height of upper surface Ftg of the portion of the fin type semiconductor layer 20 crossing the gate electrode GC. The upper surface Fg of the gate electrode GC is on the same level as, or lower than, the upper surface Fsd of the fin type semiconductor layer 20 before the epitaxial process. As a result, the spacings d1, d2 between the gate electrode GC and the contact plugs CNTs, CNTd are formed. As a result, the parasitic capacitance between the gate electrode GC and the contact plugs CNTs, CNTd decreases, and the RC delay when the word lines WL are charged, can be alleviated.

The source S and drain D contain the epitaxial layer 22. The height of the upper surface Fepi of the epitaxial layer 22 is higher than the height of the upper surface Fsd of the fin type semiconductor layer 20. As a result, the spacings d1, d2 between the gate electrode GC and the contact plugs CNTs, CNTd become even wider.

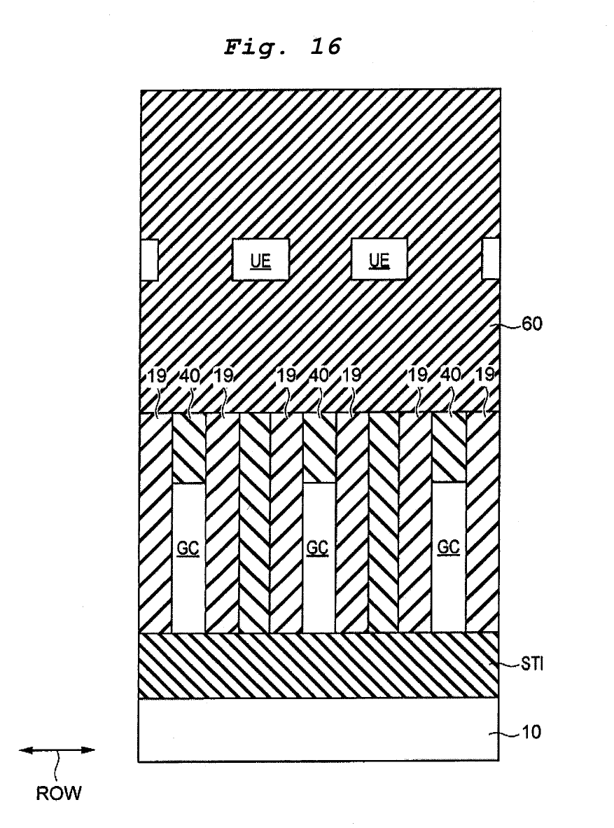

As shown in FIG. 16, on the gate electrode GC, the hard mask 40 is arranged, and, on the two side surfaces of the gate electrode GC, the side wall film 19 is formed. The side wall film 19 extends in the column direction along the gate electrode GC to cover the two side surfaces of the gate electrode GC. On the source S and drain D, the epitaxial layer 22 is deposited on the upper surface and side surface of the fin type semiconductor layer 20.

As shown in FIG. 17, on the upper portion of the source S and drain D, the silicide layer 50 is formed. As a result, it is possible to decrease the contact resistance between the contact plug CNTs and the source S, and the contact resistance between the contact plug CNTd and the drain D.

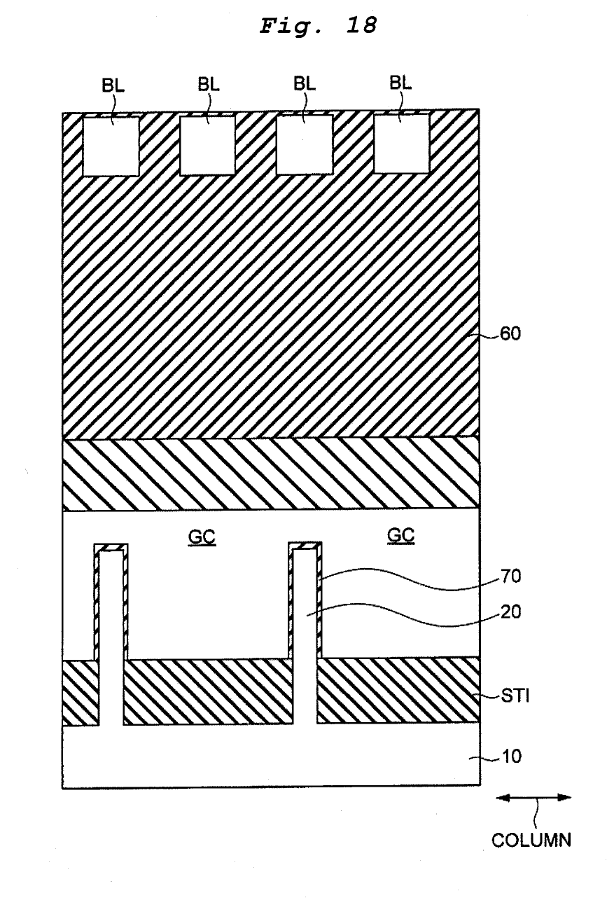

As shown in FIG. 18 and FIG. 19, the gate electrode GC extends in the column direction crossing the fin type semiconductor layer 20. The gate electrode GC faces the upper surface and side surface of the fin type semiconductor layer 20 via the gate insulating film 70. The gate electrode GC is also present on the fin type semiconductor layer 20, so that the gate electrodes GC arranged on the two side surfaces of the fin type semiconductor layer 20 are connected with each other. Consequently, the gate electrode GC works as the word line WL.

As the gate electrode GC faces the two side surfaces of the fin type semiconductor layer 20, the entirety of the channel portion of the cell transistor CT attributes to the electroconduction. As a result, according to the present embodiment, the cell transistor CT has a high current driving ability.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, the method comprising the steps of:
forming a fin in a substrate, the fin type semiconductor layer comprising multiple protrusions extending from the substrate;
forming a dummy gate electrode over and between the multiple protrusions of the fin type semiconductor layer, the dummy gate electrode disposed perpendicular to the protrusions;
forming a source region and a drain region in the fin on either side of the dummy gate;
forming an insulating film on the dummy gate electrode;
exposing the upper surface of the dummy gate electrode;
removing the dummy gate electrode to form an upper portion of a gate trench;
etching back an upper portion of the fin within the area of the dummy gate to form a lower portion of the gate trench;
on surfaces of the fin exposed in the lower portion of the gate trench, forming a gate insulating film;
forming a gate electrode in the gate trench;
etching back the gate electrode so that the uppermost surface of the gate electrode is below upper surfaces of the protrusions of the fin type semiconductor layer at the source and drain regions, wherein
in the gate trench, the gate electrode extends over a surface of the fin type semiconductor layer.

2. The method of claim 1, further comprising the step of:
forming an upper insulating film on the gate electrode.

3. The method of claim 2, wherein the upper insulating film is formed of Al₂O₃ or SiN.

4. The method of claim 3, further comprising the step of:
forming an epitaxial layer surrounding exposed surfaces of the protrusions of the fin type semiconductor layer.

5. The method of claim 4, wherein forming the source region and the drain region on the fin type semiconductor layer comprises subjecting the epitaxial layer to annealing prior to the formation of the gate electrode.

6. The method of claim 5, further comprising the step of:
forming a silicide layer on the epitaxial layer.

7. A method of manufacturing a semiconductor device, the method comprising the steps of:
forming a substrate and a fin type semiconductor layer thereon, the fin type semiconductor layer comprising multiple protrusions extending from the substrate;
forming a dummy gate electrode over and between the multiple protrusions of the fin type semiconductor layer, the dummy gate electrode disposed perpendicular to the protrusions;
forming a first interlayer insulating film on the dummy gate electrode;
exposing an upper surface of the dummy gate electrode;
removing the dummy gate electrode to form an upper part of a gate trench;
etching back the upper portion of the fin type semiconductor layer to form a lower part of the gate trench;
forming a gate insulating film on surfaces of the fin type semiconductor layer exposed in the gate trench; and
forming the gate electrode in the gate trench.

8. The method of claim 7, wherein the step of forming the gate electrode comprises the steps of:
filling the gate trench with a material used to form the gate electrode; and
etching the material used to form the gate electrode, the etching resulting in:
the uppermost surface of the gate electrode being below the uppermost surfaces of the protrusions of the fin type semiconductor layer, and
the gate electrode remains disposed over a surface of the fin type semiconductor layer in the gate trench.

9. The method of claim 8, further comprising the steps of:
forming a side wall film covering the side surface of the dummy gate electrode after forming the dummy gate electrode;
forming an epitaxial layer covering exposed surfaces of the fin type semiconductor layer, the epitaxial layer also covering a portion of an exposed surface of the side wall film on opposite sides of the dummy gate electrode;
feeding an impurity into the fin type semiconductor layer and feeding an impurity into the epitaxial layer;
subjecting the epitaxial layer to annealing to form a source region and drain region within the fin type semiconductor layer and the epitaxial layer;
after forming the first interlayer insulating film, flattening the first interlayer insulating film;
after forming the gate electrode, forming a hard mask on the upper surface of the gate electrode;
depositing a second interlayer insulating film over the epitaxial layer and the hard mask; and
forming contact plugs in the second interlayer insulating film, the contact plugs in contact with the source and the drain.

10. The method of claim 9, further comprising the step of:
after forming the gate electrode and before depositing of the second interlayer insulating film, removing the first interlayer insulating film and forming a silicide layer on the epitaxial layer.

11. The method of claim 10, wherein
the uppermost surface of the epitaxial layer is above the uppermost surface of the fin type semiconductor layer.

12. The manufacturing method of claim 11, wherein
the gate electrode is made of a metal.

13. The method of claim 12, wherein
a memory element electrically connected to the contact plugs is formed on the second interlayer insulating film.

14. A semiconductor device comprising:
a semiconductor substrate;
a fin type semiconductor layer comprising multiple protrusions extending from the semiconductor substrate;
a source region and drain region formed on the fin type semiconductor layer;
a gate electrode disposed perpendicular to the protrusions of the fin type semiconductor layer; and
an upper insulating film arranged on the upper surface of the gate electrode, wherein
the uppermost surface of the gate electrode is below the uppermost surface of the protrusions of the fin type semiconductor layer at the source region and the drain region, and
at each protrusion of the fin type semiconductor layer, a portion of the gate electrode is disposed in a cavity formed in the upper surface of the protrusion.

15. The semiconductor device according of claim 14, wherein the width of the upper insulating film is greater than the width of the gate electrode, wherein width is measured in the row direction, and wherein the row direction is the direction from the upper insulating film to a first contact plug.

16. The semiconductor device according to claim 14, wherein the semiconductor forms a transistor, the device further comprising:
a memory element above the transistor electrically connected to the source region or the drain region.

17. The semiconductor device of claim 16, wherein the upper insulating film is formed of Al₂O₃ or SiN.

18. The semiconductor device of claim 17, further including a source and a drain extending generally parallel to one another and adjacent to the gate such that the channel is interposed between the source and the drain.

19. The semiconductor device of claim 17, wherein the gate material has a melting temperature below the post implant annealing temperature of the source or the drain.

20. The semiconductor device of claim 19, wherein the gate material comprises aluminum.
